(19) United States
(12) Patent Application Publication
(10) Pub. No.: US 2008/0246041 A1
(43) Pub. Date: Oct. 9, 2008

(54) METHOD OF FABRICATING SOI nMOSFET AND THE STRUCTURE THEREOF

(75) Inventors: Yaocheng Liu, Elmsford, NY (US); Huilong Zhu, Poughkeepsie, NY (US)

Correspondence Address: HOFFMAN WARNICK LLC, 75 STATE ST, 14TH FL, ALBANY, NY, 12207, US

(73) Assignee: INTERNATIONAL BUSINESS MACHINES CORPORATION, Armonk, NY (US)

(21) Appl. No.: 11/696,846

(22) Filed: Apr. 5, 2007

(51) Int. Cl. H01L 29/12; H01L 21/336

(52) U.S. Cl. 257/77; 438/151; 257/E29.068; 257/E21.411

(57) ABSTRACT

A method of fabricating a silicon-on-insulator (SOI) N-channel metal oxide semiconductor field effect transistor (nMOSFET), where the transistor has a structure incorporating a gate disposed above a body of the SOI substrate. The body comprises of a first surface and a second surface. The second surface interfaces between the body and the insulator of the SOI. Between the first surface and second surface is defined a channel region separating a source region and a drain region. Each of the source region and drain region includes a third surface under which is embedded crystalline silicon-carbon (Si:C), which extends from the second surface to the third surface.

### BACKGROUND

1. Technical Field

The disclosure relates to metal oxide semiconductor (MOS) field effect transistor (FET) fabrication and the structure thereof. More particularly, the disclosure relates to N-channel MOSFET (nMOSFET) fabrication on silicon-on-insulator (SOI) using silicon-carbon (Si:C) to enhance electron mobility.

2. Related Art

In the current state of the art, continued complimentary metal oxide semiconductor (CMOS) scaling demands for materials with enhanced carrier mobility (i.e., holes and electrons are required to move more quickly). Enhanced carrier mobility may be achieved by a number of silicon technologies, for example: strained silicon, silicon germanium (SiGe), silicon-on-insulator (SOI) or a combination thereof. For P-channel MOSFETs (i.e., pMOSFET), silicon germanium (SiGe) is embedded in the source/drain regions to generate compressive stress in the p-channel to enhance carrier mobility. For N-channel MOSFETs (i.e., nMOSFET), silicon-carbon (Si:C) is used, for its smaller crystalline lattice constant, in the source/drain regions to generate tensile stress in the channel and enhance electron mobility.

Typically, embedded Si:C is formed by recess etching and selective epitaxial growth. The greater the thickness (or depth) of Si:C, the greater the ease in etching and hence epitaxial growth which provides better performance. However, in the case of SOI devices, the extent of the depth in the silicon layer by recess etching is limited because of the underlying buried oxide layer. Where the recess etch is too extensive in attempting to create greater depth in the SOI, the silicon may be completely removed leaving nothing or too insubstantial an amount to provide a template for Si:C epitaxial growth. This will lead to defective crystal growth and degraded device performance.

In view of the foregoing, it is desirable to develop an alternative method for forming Si:C of substantial thickness (or depth) in the source/drain regions for SOI nMOSFET devices.

### SUMMARY

A method of fabricating a silicon-on-insulator (SOI) N-channel metal oxide semiconductor field effect transistor (nMOSFET), where the transistor has a structure incorporating a gate disposed above a body of the SOI substrate. The body comprises a first surface and a second surface. The second surface interfaces between the body and the insulator of the SOI. Between the first surface and second surface is defined a channel region separating a source region and a drain region. Each of the source region and drain region includes a third surface under which is embedded crystalline silicon-carbon (Si:C), which extends from the second surface to the third surface.

A first aspect of the invention provides a silicon-on-insulator (SOI) N-channel metal oxide semiconductor field effect transistor (nMOSFET) comprising: an insulator disposed on a substrate; a body disposed on the insulator, the body having a first surface and a second surface defining a thickness therebetween, the second surface interfacing with the insulator, wherein the body includes a channel region separating a source region and a drain region, a gate disposed above the channel region on the first surface, wherein the source region and the drain region each includes a third surface under which crystalline silicon-carbon (Si:C) is embedded, the Si:C extending from the second surface through the thickness terminating at the third surface, and wherein the third surface is between the first surface and second surface.

A second aspect of the invention provides a method of fabricating a silicon-on-insulator (SOI) N-channel metal oxide semiconductor field effect transistor (nMOSFET), comprising: providing a silicon-on-insulator (SOI) structure, the structure including: a body disposed on an insulator, the body having a first surface and a second surface, the first surface and second surface defining a thickness of the body therebetween, wherein the body includes a channel region separating a source region and a drain region, wherein the source region and the drain region each includes a third surface, and wherein the third surface is between the first surface and second surface; and a gate disposed above the channel region on the first surface; amorphizing each of the source region and drain region defined between the third surface and the second surface; implanting carbon in the amorphized source region and drain region; and regrowing each of the carbon implanted source region and drain region by solid-phase epitaxy.

The illustrative aspects of the present invention are designed to solve the problems herein described and/or other problems not discussed.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIGS. 1A-1C illustrates a cross-sectional view of an embodiment of fabricating a structure of an nMOSFET.

FIGS. 2A-2E illustrates a cross-sectional view of another embodiment of fabricating a structure of an nMOSFET.

FIG. 3 illustrates a cross-sectional view of an alternative embodiment of an nMOSFET.

The accompanying drawings are not to scale, and are incorporated to depict only typical aspects of the invention. Therefore, the drawings should not be construed in any manner that would be limiting to the scope of the invention. In the drawings, like numbering represents like elements between the drawings.

### DETAILED DESCRIPTION

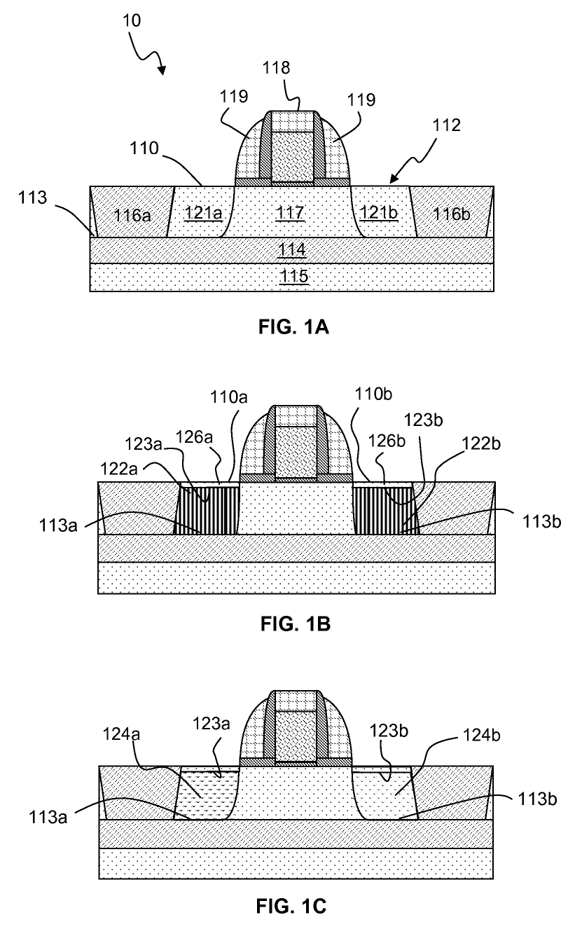

Embodiments depicted in the drawings in FIGS. 1A-3E illustrate different aspects of fabricating an nMOSFET 10 with embedded silicon-carbon (Si:C) source/drain regions.

FIG. 1A illustrates an exemplary embodiment, nMOSFET 10, fabricated by currently known or later developed complementary metal oxide semiconductor (CMOS) processes to form gate 118 and spacer 119 which are disposed on body 112. Body 112, of a thickness defined between a first surface 110 and a second surface 113, may be formed of crystalline silicon (Si). Within body 112, is defined channel region 117 that separates a source region 121a and a drain region 121b. Body 112 is disposed on insulator 114. Second surface 113 of body 112 interfaces with insulator 114. Insulator 114, commonly referred to as buried oxide (BOX), is formed from an oxide usually disposed on substrate 115. nMOSFET 10 may include shallow trench isolation (STI) regions 116a, 116b to prevent diffusion of current from body 112. When amorphization, for example, pre-amorphizing implantation (PAI), is applied to nMOSFET 10 to partially amorphize source region 121a and drain region 121b, buried amorphized silicon regions 122a, 122b are formed as shown in FIG. 1B. Buried amorphous silicon regions 122a, 122b are defined between third surfaces 123a, 123b, located at bottom of top layers 126a, 126b, and interfaces 113a, 113b. Top layers 126a, 126b of source region 121a and drain region 121b remain as crystalline silicon following partial amorphization. The amorphization process may also include implantation of germanium (Ge), xenon (Xe), silicon (Si), argon (Ar) or arsenic (As). Buried amorphous silicon regions 122a, 122b extend immediately from interface 113a to third surface 123a of crystalline silicon layer 126a and from interface 113b to third surface 123b of crystalline silicon layer 126b. As shown in FIG. 1C, buried amorphous silicon regions 122a, 122b (FIG. 1B), are implanted with carbon (C) to form a desired concentration of buried amorphous silicon-carbon (Si:C). By applying solid-phase epitaxial regrowth through an annealing process to the buried amorphous Si:C, crystalline Si:C regions 124a, 124b are formed. The solid-phase epitaxial regrowth starts from third surfaces 123a, 123b, progresses through the thickness of body 112 and terminates at interfaces 113a, 113b.

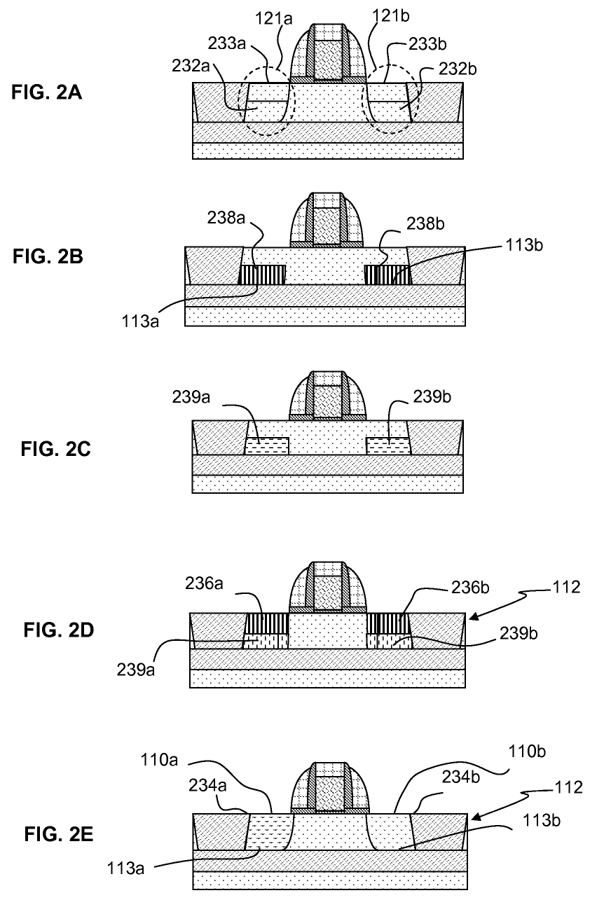

FIG. 2A-E illustrates an alternative fabrication process of nMOSFET 10 where the amorphization and regrowth processes are performed twice for each of source region 121a and drain region 121b. As shown in FIG. 2A, source region 121a is divided into a first portion 232a and a second portion 233a. Similarly, drain region 121b is divided into first portion 232b and second portion 233b. Each of first portions 232a, 232b corresponds directly to second portions 233a, 233b, respectively. Amorphization, carbon implantiation and regrowth processes of source region 121a and drain region 121b start with first portions 232a, 232b. Following completion of regrowth of first portions 232a, 232b, the amorphization and regrowth processes are repeated with second portions 233a, 233b. In FIG. 2B, amorphization of first portions 232a, 232b (FIG. 2A) form buried amorphous Si regions 238a, 238b such that the whole of each first portion 232a, 232b (FIG. 2A) is completely amorphized from interfaces 113a, 113b. Implantation of carbon is applied following the amorphization. Alternatively, the implantation may occur before the amorphization. FIG. 2C shows regrowth of buried amorphous Si regions 238a, 238b (FIG. 2B) to form crystalline Si:C region 239a, 239b. As shown in FIG. 2D, amorphization is repeated and directed to second portions 233a, 233b (FIG. 2A) to form amorphized regions 236a, 236b, each corresponding respectively to crystalline Si:C regions 239a, 239b. Amorphization to form buried amorphous regions 238a, 238b (FIG. 2B) is conducted at an energy level lower than the amorphization to form amorphized regions 236a, 236b (FIG. 2D) where ions are implanted into buried silicon. FIG. 2E shows regrowth of amorphous regions 236a, 236b (FIG. 2D) resulting in crystalline Si:C regions 234a, 234b. Crystalline Si:C regions 234a, 234b extend immediately from first surfaces 110a, 110b through the thickness of body 112 and terminate at interfaces 113a, 113b.

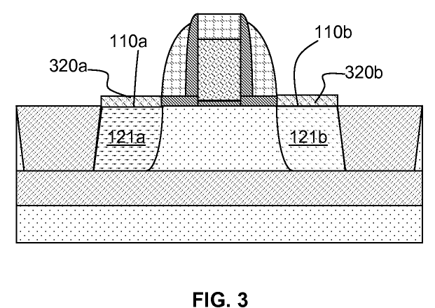

In an alternative embodiment shown in FIG. 3, nMOSFET 10 includes raised portions 320a, 320b, each respectively disposed on first surfaces 110a, 110b, respectively, above source region 121a and drain region 121b. Raised portions 320a, 320b are formed with selective silicon (Si) epitaxy and may have a thickness of approximately 2 nm to approximately 50 nm, comprising of crystalline silicon (Si) or silicon germanium (SiGe).

The foregoing description of various aspects of the invention has been presented for purposes of illustration and description. It is not intended to be exhaustive or to limit the scope of the invention to the precise form disclosed, and obviously, many modifications and variations are possible. Such modifications and variations that may be apparent to a person skilled in the art are intended to be included within the scope of the invention as defined by the accompanying claims.

What is claimed is:

1. A silicon-on-insulator (SOI) N-channel metal oxide semiconductor field effect transistor (nMOSFET) comprising:
an insulator disposed on a substrate;
a body disposed on the insulator, the body having a first surface and a second surface defining a thickness therebetween, the second surface interfacing with the insulator,
wherein the body includes a channel region separating a source region and a drain region,
a gate disposed above the channel region on the first surface,
wherein the source region and the drain region each includes a third surface under which crystalline silicon-carbon (Si:C) is embedded, the Si:C extending from the second surface through the thickness terminating at the third surface, and
wherein the third surface is between the first surface and second surface.

2. The transistor of claim 1, wherein the third surface coincides with the first surface.

3. The transistor of claim 1, wherein the third surface is below the first surface forming a layer of crystalline silicon therebetween.

4. The transistor of claim 1, further comprising a raised portion disposed on the first surface above each of the source region and the drain region.

5. A method of fabricating a silicon-on-insulator (SOI) N-channel metal oxide semiconductor field effect transistor (nMOSFET), comprising:
providing a silicon-on-insulator (SOI) structure, the structure including:
a body disposed on an insulator, the body having a first surface and a second surface, the first surface and second surface defining a thickness of the body therebetween,
wherein the body includes a channel region separating a source region and a drain region,
wherein the source region and the drain region each includes a third surface, and
wherein the third surface is between the first surface and second surface; and
a gate disposed above the channel region on the first surface;
amorphizing each of the source region and drain region defined between the third surface and the second surface;
implanting carbon in the amorphized source region and drain region; and
regrowing each of the carbon implanted source region and drain region by solid-phase epitaxy.

6. The method of claim 5, wherein the third surface coincides with the first surface.

7. The method of claim 5, wherein the third surface is below the first surface forming a layer of crystalline silicon therebetween.

8. The method of claim 5, wherein the amorphizing and regrowing is directed to a first portion of each of the source region and the drain region; and repeated to a second portion of each of the source region and the drain region.

9. The method of claim 8, wherein the first portion extends from the third surface to the second surface; and the second portion extends from the second surface to the first surface.
